(19) United States
(12) Patent Application Publication
(10) Pub. No.: US 2009/0294630 A1
(43) Pub. Date: Dec. 3, 2009

(54) IMAGE SENSOR, IMAGE READING DEVICE AND PRODUCTION METHOD OF IMAGE SENSOR

(75) Inventors: Tomihisa Saito, Tokyo (JP); Takashi Kishimoto, Tokyo (JP); Hidemitsu Takeuchi, Tokyo (JP); Takeshi Ishimaru, Tokyo (JP); Masahide Wakisaka, Tokyo (JP)

Correspondence Address: RATNERPRESTIA, P.O. BOX 980, VALLEY FORGE, PA, 19482, US

(73) Assignee: NIPPON SHEET GLASS COMPANY, LIMITED, Tokyo (JP)

(21) Appl. No.: 11/917,254

(22) PCT Filed: Jun. 6, 2006
(86) PCT No.: PCT/JP2006/311317

§ 371 Date: Jun. 25, 2009

(30) Foreign Application Priority Data
Jun. 21, 2005 (JP) 2005180322

(51) Int. Cl. H01L 27/00

(52) U.S. Cl. 250/208.1

(57) ABSTRACT

An image sensor and a manufacturing method thereof are provided, so that the warp or the distortion is not caused even if there is the thermal expansion difference or the thermal contraction difference in the longitudinal direction between the linear illuminating device and the frame. The image sensor comprises a linear illuminating device for illuminating an original; a light-receiving element array for receiving reflected light from the original; a lens array for focusing the original on the light-receiving element array; a frame for containing the linear illuminating device, the lens array, and the light-receiving element array; and a resilient retaining portion for pressing the linear illuminating device, which is mounted in the frame, into the frame.

### TECHNICAL FIELD

The present invention relates to a contact image sensor provided a linear illuminating device, an image reading apparatus provided the contact image sensor, and a method for manufacturing of the contact image sensor provided the linear illuminating device.

### RELATED ART

A contact image sensor is used for a device in an image reading apparatus, such as a facsimile, an electro-photographic apparatus, and an image scanner, to read the image information of an original. This contact image sensor comprises a linear illuminating device for linearly illuminating the original in a main-scanning direction. For the image reading apparatus, the contact image sensor may read the image information of the original by scanning the image sensor in a sub-scanning direction with reading the image information of the original, or by scanning the original in a sub-scanning direction, in which the contact image sensor is fixed in the image reading apparatus.

One type using a light guide is known as a linear illuminating device. One or more light-emitting elements are arranged in one end of the light guide, and light-diffusing patterns in the light guide are formed over the main-scanning direction of the light guide to diffuse or reflect the light irradiated from the light-emitting element. The light guide is made of the material of optical transparency. Light that diffuses or reflects in the inside of the light guide is irradiated from the irradiation side surface of the light guide (for example, refer to Japanese Patent Application Laid-Open No. 2004-56425).

FIG. 17 is a cross-sectional view showing the structure of a conventional image sensor. The light irradiated from a linear illuminating device 110 penetrates an original glass plate 102 of optical transparency, and irradiates original G as shown by optical paths La and Lb. The reflected light from original G is focused by a lens array 105, and entered into a light-receiving element array 103 provided on a sensor substrate 104. The linear illuminating device 110 comprises a light guide 111 of optical transparency and a case 112, and an optically scattering or diffusing portion 120 is formed in the bottom of the light guide 111. The linear illuminating device 110 is arranged into V-shaped hollows 101a provided in a frame (case) 101 of the image sensor. An adhesive or a double-faced tape is used to fix the linear illuminating device 110 to the V-shaped hollows 101a.

However, there are the following problems when the linear illuminating device 110 is fixed to the frame 101 with the adhesive or the double-faced tape. First, if the material of the linear illuminating device 110 (in which the resin is mainly used) and the material of the frame 101 are different, the thermal expansion difference and the thermal contraction difference exist between both materials. Therefore, if the linear illuminating device 110 causes the thermal expansion or the thermal contraction in a longitudinal direction thereof (i.e. the main-scanning direction), some trouble may be caused due to the stress of the contacted part between the linear illuminating device 110 and the frame 101, such as the warp of the image sensor.

Moreover, the arrangement position of the linear illuminating device 110 cannot be changed, since the hollow 101a of the frame 101 is provided as a fixed position. Thereby, there is a problem that fine-tuning of the illuminating range with the linear illuminating device becomes difficult. The illumination performance (brightness and illumination depth, etc.) should be varied by the arrangement position of the linear illuminating device. In addition, the illumination performance requested for some application with the image sensor may be different (for example, the image-reading for the front side or the back side of the original). Therefore, several kinds of the frame will have to be manufactured in order to manufacture an image sensor for different application, so that the position of the hollow portion is different. Thus, there is a problem of hindering the low-cost of the image sensor.

In addition, since the linear illuminating device 110 is bonded and is fixed into the frame 101, it will be difficult to detach only the linear illuminating device 110 from the assembled image sensor, for example for recycling. Even if the linear illuminating device 110 can be detached, some problem may be caused that the linear illuminating device 110 is transformed, and that the illuminating side surface of the linear illuminating device 110 becomes dirty. Moreover, even if the cause of defect of the image reading apparatus is determined as only the linear lighting device 110 of the image sensor, the whole image sensor might be exchanged since it is difficult to exchange only the linear illuminating devices 110.

Consequently, while the linear illuminating device is bonded and fixed into the frame, one technique for solving the distortion and the warp of the image sensor caused by the thermal expansion or the thermal contraction is disclosed (for example, refer to Japanese Patent Application Laid-Open No. 2005-223424). According to the technique, a hollow portion for fixing of the linear illuminating device is formed in the frame of the image sensor, in which the length of the hollow portion of the frame in the longitudinal direction (i.e. the main-scanning direction) is longer than the entire length of the linear illuminating device, and an elastic material is provided in the space between the linear illuminating device and the frame. In this way, the linear illuminating device is mechanically fixed to the image sensor frame.

### DISCLOSURE OF THE INVENTION

In recent years, an image reading apparatus which enables reading of an original of the A3 or more size of the original has been requested. Similarly, an image sensor for the A3 or more size of the original has been requested. For the image sensor reading the A3 or more size of the original, there is a problem in the prior art that the more rigid material for forming the image sensor is requested so as to reduce the warp of the image sensor in the longitudinal direction.

Moreover, since the technique of providing the elastic material disclosed in Japanese Patent Application Laid-Open No. 2005-223424 is to press the linear illuminating device in the longitudinal direction by the elastic material provided in the space between the linear illuminating device and the frame, the elastic material with a suitable elastic coefficient for each image sensor of different size in the longitudinal direction have to be found in every condition.

The object of the present invention is to provide an image sensor in which the warp or the distortion is not caused even if there is the thermal expansion difference or the thermal contraction difference in the longitudinal direction between the linear illuminating device and the frame, to provide an image sensor which enables change of the arrangement position of the linear illuminating device in the frame easily, to provide an image sensor which enables detaching of the linear illuminating device from the frame easily, and to provide an image sensor in which the warp is not caused in the longitudinal direction even if the image sensor of large-scale size is formed by any materials of a low rigidity, such as resin.

An image sensor in accordance with the present invention comprises a linear illuminating device for illuminating an original; a light-receiving element array for receiving reflected light from the original; a lens array for focusing the original on the light-receiving element array; a frame for containing the linear illuminating device, the lens array, and the light-receiving element array; and a resilient retaining portion for pressing the linear illuminating device, which is mounted in the frame, into the frame. The resilient retaining portion may be a part of the frame. In this image sensor, the resilient retaining portion may be a structure in which whole position of the longitudinal direction of the linear illuminating device are pressed. Alternatively, the resilient retaining portion may be a structure in which a plurality of local positions of the longitudinal direction of the linear illuminating device are pressed. Moreover, two linear illuminating devices may be provided to be an opposed position in both sides of the lens array.

An image sensor in accordance with further aspect of the present invention comprises a linear illuminating device for illuminating an original; a light-receiving element array for receiving reflected light from the original; a lens array for focusing the original on the light-receiving element array; a frame for containing the linear illuminating device, the lens array, and the light-receiving element array; and a resilient retaining material for pressing the linear illuminating device, which is mounted in a hollow portion of the frame, into the frame. In this image sensor, the resilient retaining material and the linear illuminating device are fixed by a combining technique. In this image sensor, the resilient retaining material may be a structure in which whole position of the longitudinal direction of the linear illuminating device are pressed. Alternatively, the image sensor may be a structure in which a plurality of local positions of the longitudinal direction of the linear illuminating device are pressed. Moreover, two linear illuminating devices may be provided to be an opposed position in both sides of the lens array.

An image sensor in accordance with further aspect of the present invention comprises a linear illuminating device for illuminating an original; a light-receiving element array for receiving reflected light from the original; a lens array for focusing the original on the light-receiving element array; a frame for containing the linear illuminating device, the lens array, and the light-receiving element array; and a resilient retaining material for pressing the linear illuminating device, which is mounted in a hollow portion of the frame, into the frame; wherein the width of a shorter-side direction of the hollow portion formed in the frame is longer than the width of the shorter-side direction of the linear illuminating device. In this image sensor, the resilient retaining material and the linear illuminating device are fixed by a combining technique. In addition, this image sensor may comprise an alignment material for aligning the linear illuminating device in the shorter-side direction, and/or an angle-adjusting material for adjusting the irradiation angle of the linear illuminating device, wherein the alignment material and the angle-adjusting material may be provided in the hollow portion formed in the frame. Moreover, two linear illuminating devices may be provided to be an opposed position in both sides of the lens array.

An image sensor in accordance with further aspect of the present invention comprises a linear illuminating device for illuminating an original, the linear illuminating device including a light guide, and a case for covering a part of the light guide; a light-receiving element array for receiving reflected light from the original; a lens array for focusing the original on the light-receiving element array; a frame for containing the linear illuminating device, the lens array, and the light-receiving element array; and a resilient retaining material for pressing the linear illuminating device, which is mounted in a hollow portion of the frame, into the frame; wherein the resilient retaining material is formed over longitudinal direction of the linear illuminating device to cover at least one side surface of the light guide, the at least one side surface of the light guide being not covered by the case. In addition, a reflecting portion may be provided on a part of the case for reflecting the irradiated light from the light guide. The lens array may be composed of at least one or more lens plates that have a plurality of minute lenses in two-dimensional array.

An image sensor in accordance with further aspect of the present invention comprises a linear illuminating device for illuminating an original; a light-receiving element array for receiving reflected light from the original; a lens array for focusing the original on the light-receiving element array; a frame for containing the linear illuminating device, the lens array, and the light-receiving element array; and a detachable retaining material for pressing the linear illuminating device, which is mounted in the frame, into the frame.

An image sensor in accordance with further aspect of the present invention comprises a linear illuminating device for illuminating an original; a light-receiving element array for receiving reflected light from the original; a lens array for focusing the original on the light-receiving element array; a frame for containing the linear illuminating device, the lens array, and the light-receiving element array; and a detachable retaining material for pressing the linear illuminating device, which is mounted in a hollow portion of the frame, into the frame.

An image sensor in accordance with further aspect of the present invention comprises a linear illuminating device for illuminating an original; a light-receiving element array for receiving reflected light from the original; a lens array for focusing the original on the light-receiving element array; a frame for containing the linear illuminating device, the lens array, and the light-receiving element array; and a detachable retaining material for pressing the linear illuminating device, which is mounted in a hollow portion of the frame, into the frame; wherein the width of a shorter-side direction of the hollow portion is longer than the width of the shorter-side direction of the bottom of the linear illuminating device.

A method for manufacturing an image sensor in accordance with further aspect of the present invention, in which the image sensor comprises a linear illuminating device for illuminating an original; a light-receiving element array for receiving reflected light from the original; a lens array for focusing the original on the light-receiving element array; a frame for containing the linear illuminating device, the lens array, and the light-receiving element array; and a resilient retaining portion for pressing the linear illuminating device, which is mounted in a hollow portion of the frame, into the frame, wherein the width of a shorter-side direction of the hollow portion is longer than the width of the shorter-side direction of the linear illuminating device; the method comprising the steps of arranging an alignment material into the hollow portion; arranging the linear illuminating device within the hollow portion based on the arrangement of the alignment material; and removing the alignment material after fixing the linear illuminating device into the frame using the alignment material.

### BRIEF DESCRIPTION OF THE DRAWINGS

FIG. 1 is a cross-sectional view of an image sensor of a first embodiment and a second embodiment in accordance with the present invention;

FIG. 2 is a cross-sectional view of an image sensor of a third embodiment and a fourth embodiment in accordance with the present invention;

FIG. 3 is a perspective cross-sectional view of the image sensor of the first embodiment in accordance with the present invention;

FIG. 4 is a perspective cross-sectional view of the image sensor of the second embodiment in accordance with the present invention;

FIG. 5 is a perspective cross-sectional view of the image sensor of the third embodiment in accordance with the present invention;

FIG. 6 is a perspective cross-sectional view of the image sensor of the fourth embodiment in accordance with the present invention;

FIG. 7 is a cross-sectional view of an image sensor of a fifth embodiment in accordance with the present invention;

FIG. 8 is a perspective cross-sectional view of an image sensor of further aspect of the fifth embodiment in accordance with the present invention;

FIG. 9 is a cross-sectional view for showing a manufacturing method of the image sensor of the fifth embodiment in accordance with the present;

FIG. 10 is a cross-sectional view of an image sensor of a sixth embodiment in accordance with the present invention;

FIG. 11 is a cross-sectional view of an image sensor of a seventh embodiment in accordance with the present invention;

FIG. 12 is a cross-sectional view of an image sensor of an eighth embodiment in accordance with the present invention;

FIG. 13 is a cross-sectional view of an image sensor of a ninth embodiment in accordance with the present invention;

FIG. 14 is a perspective view of a linear illuminating device used for the image sensor of the ninth embodiment in accordance with the present invention;

FIG. 15 is a cross-sectional view of an image sensor of a tenth embodiment in accordance with the present invention;

FIG. 16 is a cross-sectional view of an image sensor of an eleventh embodiment in accordance with the present invention;

FIG. 17 is a cross-sectional view of a conventional image sensor;

FIG. 18 is a schematic illustration of an image scanner including an image sensor in accordance with the present invention; and

FIG. 19 is a schematic illustration of an electro-photographic apparatus including an image sensor in accordance with the present invention.

### BEST MODE FOR CARRYING OUT THE INVENTION

Hereinafter, while some embodiments are described with reference to the drawings, these embodiments do not limit any scope of the present invention. Moreover, for the identical or similar elements shown in each drawing, the same reference signs are designated.

First of all, a first embodiment of an image sensor in accordance with the present invention is described.

### A First Embodiment

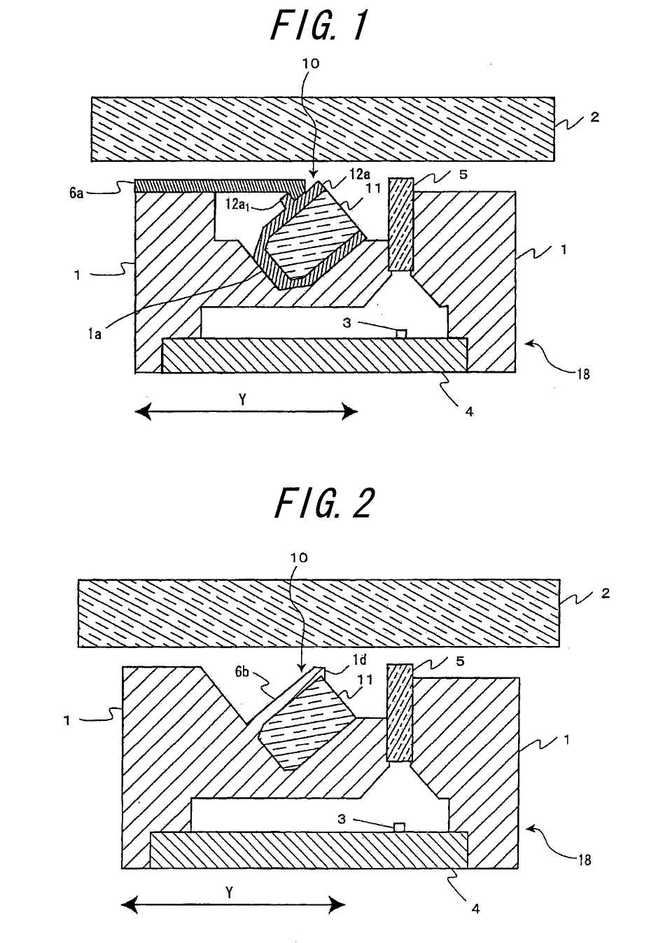

FIG. 1 is a cross-sectional view of an image sensor of a first embodiment in accordance with the present invention. An image sensor 18 comprises a frame 1, a lens array 5, a linear illuminating device 10, and a sensor substrate 4 provided with a light-receiving element array 3. The lens array 5, the linear illuminating device 10, and the sensor substrate 4 provided with the light-receiving element array 3 are contained into the frame 1.

The linear illuminating device 10 comprises a light guide 11, a case 12a, and light-emitting elements (not shown). In general, the light-emitting elements, which may include one or more light-emitting elements (for example, LED), may be arranged in one end or both ends of the linear illuminating device 10. The light irradiated from the light-emitting elements is irradiated from the irradiation side surface of the light guide 11, repeating the reflection within light guide 11. High reflection efficiency in the light guide 11 may be achieved, if the case 12a is provided with white color. Moreover, any reflecting or scattering patterns may be formed on a plurality of surfaces of the light guide 11 to reflect or scatter the light. The reflecting or scattering patterns may be made of any white-printing technique or any concavo-convex surface technique.

The light irradiated from the light guide 11 passes an original glass plate 2 which is composed of optical transparency materials, such as glass material, and irradiates an original put on the original glass plate 2. The reflected light from the original is focused by the lens array 5 to enter the light-receiving element array 3 provided in sensor substrate 4. The lens array 5 may comprise a plurality of rod lens arrays that are arranged in two rows, to establish an erecting unit magnification system. Thus, the original is irradiated with the linear illuminating device 10, and the image information for one line in the original is focused on the light-receiving element array 3. Thereby, reading the image information of the original may be performed. The image sensor 18 may move by one line in the sub-scanning direction (i.e. the direction indicated by an arrow Y shown in FIG. 1) to read sequent one line similarly after reading one line of the original. Repeating this operation, the image information in the original may be read by means of the image sensor 18.

In this embodiment, a convex portion 12a₁ has been formed in the side of the case 12a of the linear illuminating device 10, which comprises the light guide 11 and the case 12a. A hollow portion 1a and a resilient retaining material 6a have been provided in the frame 1 to retain the linear illuminating device 10. The resilient retaining material 6a and the convex portion 12a₁ are combined to fix the linear illuminating device 10. If the case 12a is not used, a convex portion may be formed on the side surface of the light guide 11, so that the convex portion is combined with the resilient retaining material 6a. In addition, such convex portion may be provided over the entire length of the longitudinal direction (i.e. the main-scanning direction) in the linear illuminating device 10 or may be formed for a part of the longitudinal direction.

The frame 1 is made of resin, and the resilient retaining material 6a is mainly made of metallic material or resin, but any materials may be used therefor as long as the resilient retaining material 6a is elastic material. The resilient retaining material 6a may have certain degree of elasticity so as to facilitate to detach the linear illuminating device 10. In FIG. 1, the resilient retaining material 6a is composed of a plate spring structure, but the resilient retaining material may be composed of another spring structure. The resilient retaining material 6a may be fixed into the frame 1 by screws or by adhesion, such as adhesive material, or by hot gluing or by an ultrasonic caulking technique. Alternatively, the resilient retaining material 6a may be fixed into the frame 1 by insert molding on the injection molding of the frame 1.

If both of the frame 1 and the resilient retaining material 6a are made of resin, the frame 1 and the resilient retaining material 6a may be integrated by ultrasonic bonding. Alternatively, the frame 1 and the resilient retaining material 6a may be of integrated molding.

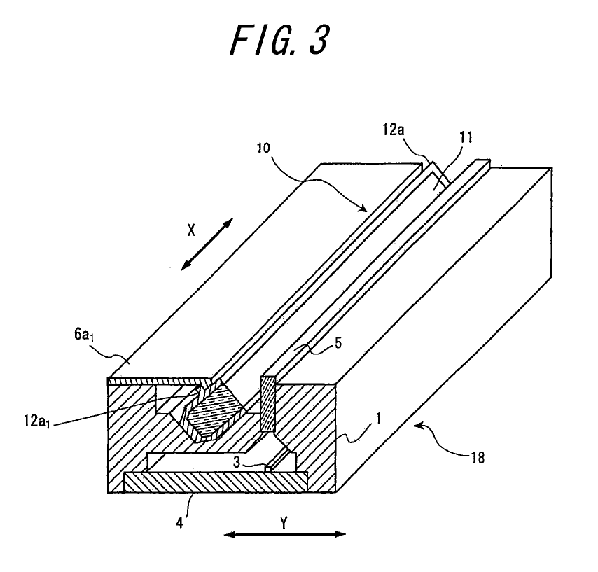

FIG. 3 is a perspective cross-sectional view of the image sensor of the first embodiment in accordance with the present invention. In the first embodiment, a resilient retaining material 6a₁ shown in FIG. 3 has a function similar to the resilient retaining material 6a shown in FIG. 1. The resilient retaining material 6a₁ may be provided over the entire length of the longitudinal direction (i.e. the main-scanning direction indicated by an arrow X shown in FIG. 3) in the image sensor 18. The convex portion 12a₁ of the side of the case for combining with the resilient retaining material 6a₁ may be provided over the entire length of the longitudinal direction in the case 12a. In this embodiment, the resilient retaining material 6a₁ has not only the effect of fixing into the case 12a but also the effect of preventing the distortion or the warp of the longitudinal direction in the image sensor 18. For a longer image sensor for reading image information in A3 or more size of the original, the distortion or the warp of the longer image sensor 18 may be easily caused in the longitudinal direction. Thus, it is preferable to provide the resilient retaining material 6a₁ over the entire length of the longitudinal direction in the linear illuminating device, as disclosed in this embodiment.

Then, a second embodiment of an image sensor in accordance with the present invention is described.

### A Second Embodiment

Since a cross-sectional view of an image sensor in a second embodiment is similar to FIG. 1 described in the first embodiment, the detailed description is omitted.

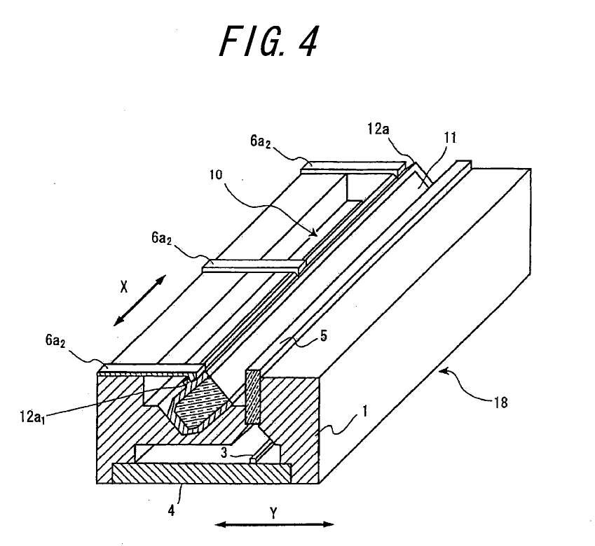

FIG. 4 is a perspective cross-sectional view of an image sensor of a second embodiment in accordance with the present invention. In the second embodiment, each of resilient retaining materials 6a₂ shown in FIG. 4 has a function similar to the resilient retaining material 6a shown in FIG. 1. In this embodiment, the convex portion 12a₁ in the side of the case 12a is formed over the entire length of the longitudinal direction in the case 12a. On the other hand, each of the resilient retaining materials 6a₂ has been arranged in three places of the center and both ends of the longitudinal direction (i.e. the main-scanning direction indicated by an arrow X shown in FIG. 4) in the linear illuminating device 10. Therefore, the plurality of the resilient retaining materials 6a may be formed at optional interval over the longitudinal direction in the linear illuminating device 10 to press the local positions of the longitudinal direction in the linear illuminating device 10 into the frame 1. As a result, it becomes extremely easy to assemble the linear illuminating device 10 into the frame 1 or to detach the linear illuminating device 10 from the frame 1. It is preferable to provide the resilient retaining materials 6a₂ in two places of both ends of the longitudinal direction in the linear illuminating device 10 in order to preferably maintain the linear illuminating device. More particularly, it is preferable to provide the resilient retaining materials 6a₂ in the center of the longitudinal direction in the linear illuminating device 10, not only to provide in the two places of both ends thereof in order to suitably suppress the distortion or the warp of the image sensor 18 in the longitudinal direction, as shown in FIG. 4. That is, it is preferable to provide resilient retaining materials 6a₂ in three or more places. The width and the number of the resilient retaining materials 6a₂ may be suitably provided in consideration of the size or the shape etc. of the image sensor 18, the linear illuminating device 10, and the frame 1. Then, a third embodiment of an image sensor in accordance with the present invention is described.

### A Third Embodiment

FIG. 2 is a cross-sectional view of an image sensor of a third embodiment in accordance with the present invention. In FIG. 2, the frame 1 and a resilient retaining portion 6b are of integrated molding. This image sensor structure is similar to the first embodiment or the second embodiment, excluding the structure of an linear illuminating device 10, as well as a frame 1 and the resilient retaining portion 6b formed by integrated molding. Therefore, only the features of this embodiment are described.

In this embodiment, the resilient retaining portion 6b also functions as a case of the light guide 11. It is preferable to provide the contact part between the light guide 11 and the frame 1 and the contact part between the light guide 11 and the resilient retaining portion 6a with white color in order to reduce loss of amount of light irradiated from the light guide 11. For providing the frame 1 and the resilient retaining portion 6b with white color, several techniques may be used, such as the technique of posting a white film into the contact part of the light guide 11, the technique of painting the contact part with white color, such as two color molding, the technique of molding the entire of the frame 1 with resin of white color, or the like. If the entire of the frame 1 is molded with resin of white color, light-shielding materials should be arranged around the linear illuminating device 10, the rod lens array 5 and the sensor substrate 4 in order to prevent entering of any undesired light.

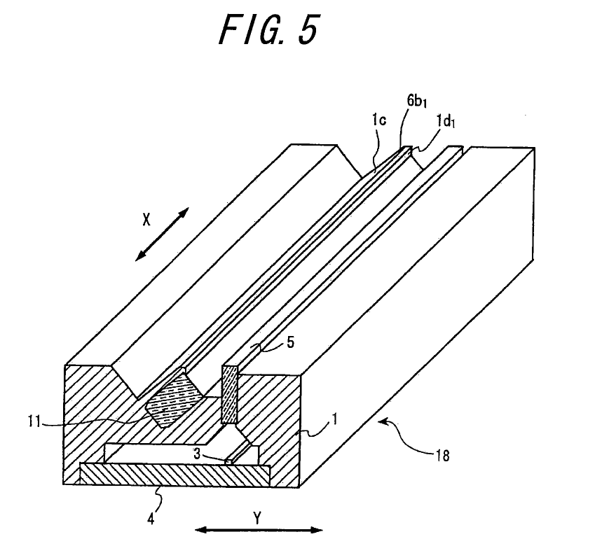

FIG. 5 is a perspective cross-sectional view of an image sensor of the third embodiment in accordance with the present invention. In the third embodiment, the resilient retaining portion 6b₁ shown in FIG. 5 has a function similar to the resilient retaining portion 6b shown in FIG. 2. In addition, a hooking portion 1d₁ of the resilient retaining portion 6b₁ shown in FIG. 5 has a function similar to a hooking portion 1d of the resilient retaining portion 6b shown in FIG. 2. In this embodiment, the resilient retaining portion 6b₁ has been provided over the entire length of the light guide 11 (i.e. in the main-scanning direction indicated by an arrow X shown in FIG. 5). The resilient retaining portion 6b₁ is composed of a planar portion 1c that functions as the case of the light guide 11, and a hooking portion 1d₁ for fixing the light guide 11. In this embodiment, the number of components may be decreased to reduce the cost, because the resilient retaining portion 6b and the frame 1 are of integrated molding. Moreover, it can ensure that the light guide 11 is fixed, because the hooking portion 1d₁ is provided over the entire length of the longitudinal direction in the light guide 11.

Then, a fourth embodiment of an image sensor in accordance with the present invention is described.

### A Fourth Embodiment

Since a cross-sectional view of an image sensor in a fourth embodiment is similar to FIG. 2 described in the third embodiment, the detailed description is omitted.

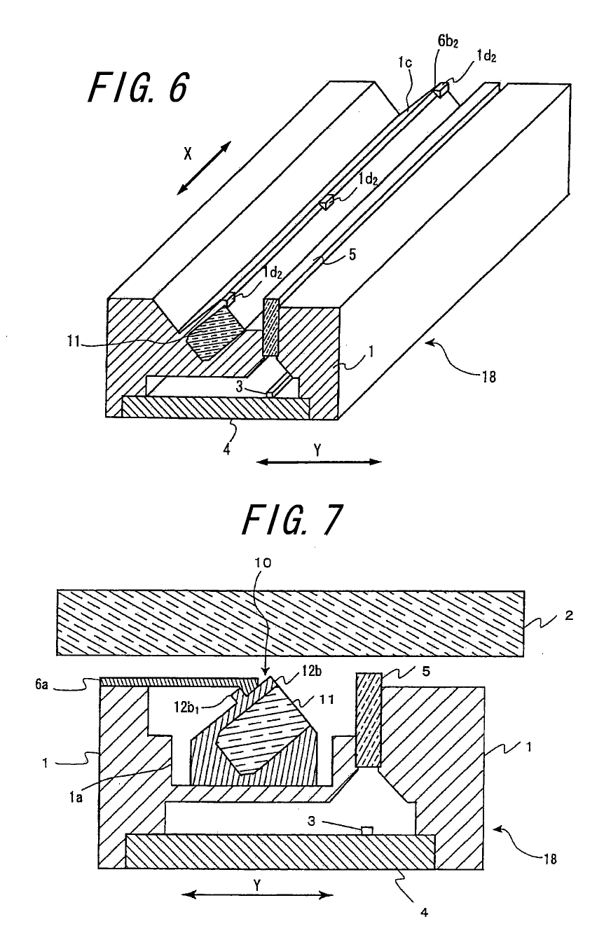

FIG. 6 is a perspective cross-sectional view of an image sensor of a fourth embodiment in accordance with the present invention. In the fourth embodiment, the resilient retaining portion 6b₂ shown in FIG. 6 has a function similar to the resilient retaining portion 6b shown in FIG. 2. In addition, a hooking portion 1d₂ of the resilient retaining portion 6b₂ shown in FIG. 6 has a function similar to the hooking portion 1d of the resilient retaining portion 6b shown in FIG. 2. This embodiment is similar to the third embodiment, excluding locally arranged hooking portions 1d₂ in the resilient retaining portion 6b₂. Since the hooking portions 1d₂ of the resilient retaining portion 6b₂ has been locally arranged in the longitudinal direction in this embodiment, the loss of the amount of irradiated light based on shielding of the hooking portions 1d₂ may be reduced. The amount of irradiated light may be adjusted and uniformed by suitably setting the number, the width, and the position of the hooking portions 1d₂. For example, if a light source is arranged in one end of the longitudinal direction of the light guide 11, the amount of irradiated light may be decreased according to keeping away as the distance from the light source. Thus, in near area from the light source, the width of each hooking portion 1d₂ may be larger, and the distance between the hooking portions 1d₂ may be shorter. Moreover, in far area from the light source, the width of each hooking portion 1d₂ may be shorter, and the distance between the hooking portions 1d₂ may be longer. In this manner, the uniformity of the amount of irradiated light from the linear illuminating device may be obtained.

Then, a fifth embodiment of an image sensor in accordance with the present invention is described.

### A Fifth Embodiment

FIG. 7 is a cross-sectional view of an image sensor of a fifth embodiment in accordance with the present invention. In the fifth embodiment, this image sensor structure is similar to the image sensor structure shown in the first embodiment or the second embodiment, excluding the bottom of the hollow portion 1a of the frame 1 provided with plane, and the bottom of the case 12b provided with plane. In the fifth embodiment, the case 12b has a movable structure in the sub-scanning direction (i.e. the direction indicated by the arrow Y shown in FIG. 7) of the image sensor 18. The suitable position of the linear illuminating device 10 provided in the hollow portion 1a may be different according to the shape, the size, and the arrangement angle of the light guide 11, as well as the shape of the lens array 5 and these optical performance. According to this embodiment, the linear illuminating device 10 may be fixed into the frame 1 by combining the resilient retaining material 6a with the convex portion 12b, of the side of the case 12b, after moving the linear illuminating device 10 to the suitable position and aligning the linear illuminating device 10 in sub-scanning direction. Thus, even if any design change of the light guide 11 is performed, the shape of the hollow portion 1a of the frame 1 does not need to be changed based on the changed light guide 11. Moreover, the position of the linear illuminating device 10 may be fine-tuned in the sub-scanning direction. The hollow portion 1a and the case 12b may be of any shape if the linear illuminating device 10 can be freely moved in the sub-scanning direction within the hollow portion 1a of the case 12b. For example, the bottom of the hollow portion 1a may be an inclined plane. That is, each surface of contact part between the hollow portion 1a and the case 12b is requested only to be a parallel plane. Moreover, the shape of the case 12b may be a shape that a part of the bottom of the case 12b contacts with the hollow portion 1a.

Then, further aspect of the fifth embodiment of an image sensor in accordance with the present invention is described.

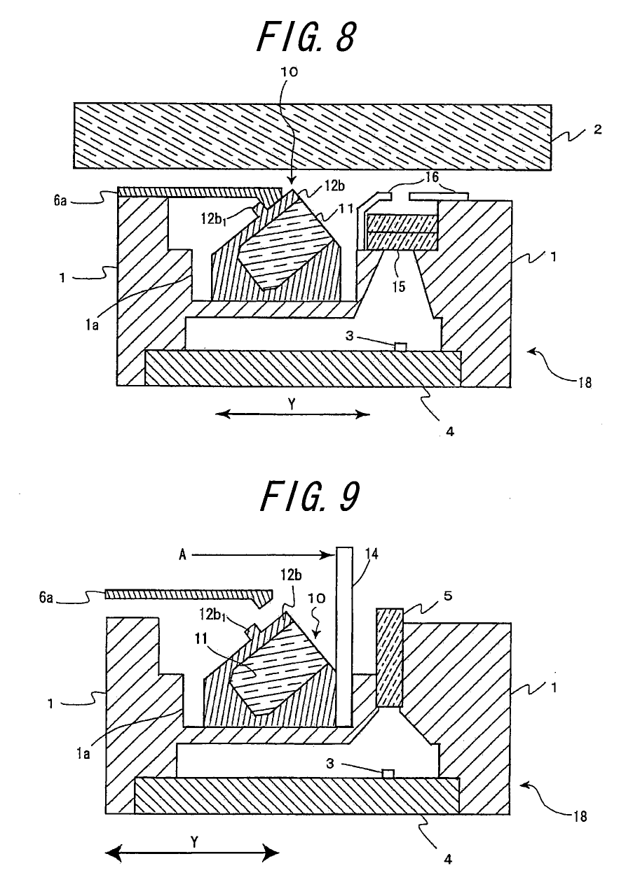

FIG. 8 is a perspective cross-sectional view of an image sensor of further aspect of the fifth embodiment in accordance with the present invention. This image sensor structure is similar to the image sensor structure of the fifth embodiment, excluding the lens array 5 shown in FIG. 7 replaced with a planar lens array plate 15, and a slit 16 for shielding any stray light. In this embodiment, the height of the image sensor 18 may be reduced to miniaturize an image reading apparatus, since the erecting unit magnification system consists of two planar lens array plates 15.

Then, a method for manufacturing the image sensor of the fifth embodiment in accordance with the present invention is described.

FIG. 9 is a cross-sectional view for showing a manufacturing method of the image sensor of the fifth embodiment in accordance with the present. At first, after arranging an alignment material 14 for aligning the linear illuminating device 10 into the hollow portion 1a of the frame 1, the linear illuminating device 10 may be arranged onto the bottom of the hollow portion 1a. Then, the linear illuminating device 10 may be moved in the sub-scanning direction (i.e. the direction of Y shown in the FIG. 9), and adapted to the alignment material 14. Then, in the condition that the illuminating device has been adapted to the alignment material 14, one end of resilient retaining material 6a may be combined with the convex portion 12b, of the case 12b. Finally, the other end of the resilient retaining material 6a may be fixed into the frame 1. In this way, the alignment material 14 may be detached from the frame 1 after fixing the linear illuminating device 10 into the hollow portion 1a. The alignment material 14 may be a rod-shape or a planar-shape, which is extended in the longitudinal direction of the image sensor 18. If the rod-shape is used for the alignment materials 14, it is preferable to arrange the rod-shaped alignment materials 14 into at least both sides of the linear illuminating device 10, respectively. According to this manufacturing method, it enables alignment of the linear illuminating device 10 easily, due to use of the alignment material 14.

Then, a sixth embodiment of an image sensor in accordance with the present invention is described.

### A Sixth Embodiment

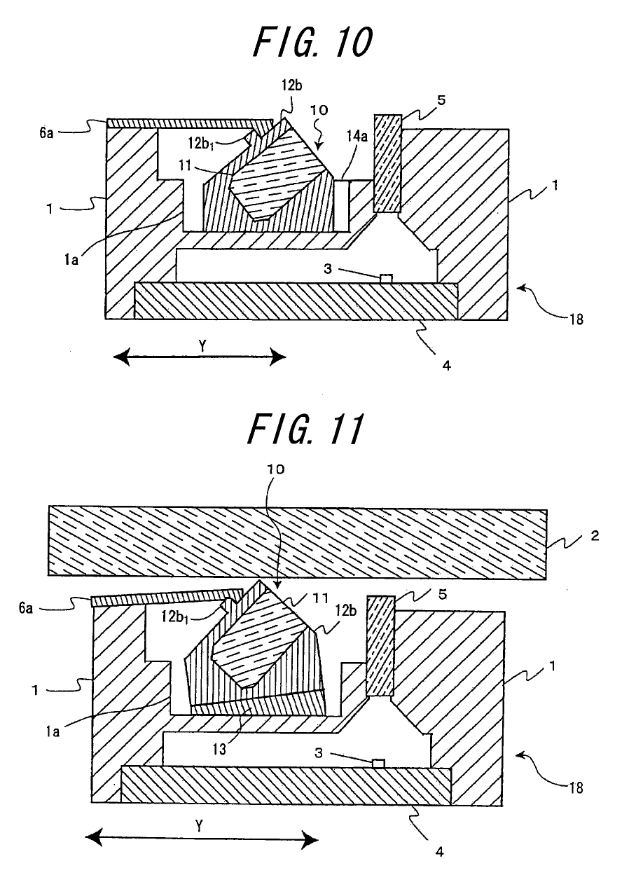

FIG. 10 is a cross-sectional view of an image sensor of a sixth embodiment in accordance with the present invention. The image sensor of this embodiment may be manufactured without removing the alignment material 14a in the manufacturing method of the image sensor shown in FIG. 9, so that the alignment material 14a remains the arrangement position. Since an alignment material 14a shown in FIG. 10 has a function similar to the alignment material shown in FIG. 9, the description is omitted. In this embodiment, the linear illuminating device 10 may be fixed together with both of the resilient retaining material 6a and the alignment material 14a into the image sensor. The height and the shape of the alignment material 14a may be designed without shielding the irradiated light from the linear illuminating device 10.

Then, a seventh embodiment of an image sensor in accordance with the present invention is described.

### A Seventh Embodiment

FIG. 11 is a cross-sectional view of an image sensor of a seventh embodiment in accordance with the present invention. The image sensor structure shown in FIG. 11 is similar to the image sensor structure of the fifth embodiment, excluding an angle-adjusting material 13 added to adjust the irradiation angle of the linear illuminating device and arranged on the bottom of the case 12b. According to this embodiment, the irradiation angle of the linear illuminating device 10 may be changed by changing the angle of gradient on a top side of an angle-adjusting material 13 (i.e. the contacted surface to the case 12b). In addition, if the angle-adjusting material 13 is made of an elasticity material, the arrangement position of the linear illuminating device 10 may be fine-tuned.

Then, an eighth embodiment of an image sensor in accordance with the present invention is described.

### An Eighth Embodiment

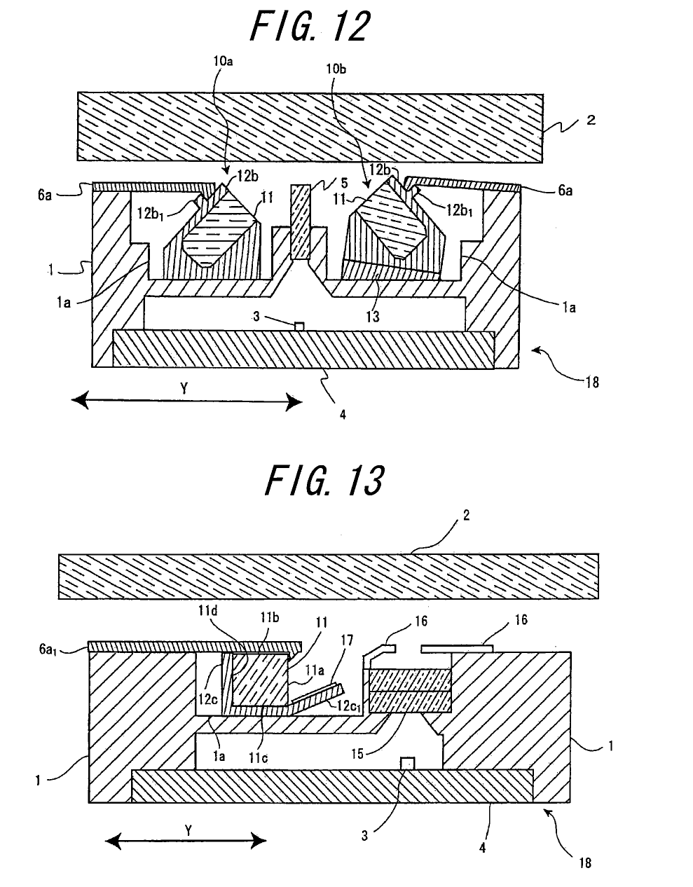

FIG. 12 is a cross-sectional view of an image sensor of an eighth embodiment in accordance with the present invention. In this embodiment, two linear illuminating devices 10 are arranged on both sides of the lens array 5. The linear illuminating devices 10a and 10b are similar to the linear illuminating device 10 shown in above-mentioned FIG. 7. That is, the light guide 11 and the case 12 used for the linear illuminating devices 10a and 10b are the same structure, mutually. The angle-adjusting material 13 to adjust the irradiation angle of the linear illuminating device 10b may be arranged under the linear illuminating device 10b. In this embodiment, the irradiation angle of each of two linear illuminating devices 10a and 10b may be designed to be mutually different in the image sensor 18. Thus, the irradiation range of each of two linear illuminating devices 10a and 10b may be also different. As a result, the image sensor may be implemented to obtain a high-quality image by enlarged illuminating depth in illumination system of the image sensor 18, even if the original is set on the original glass plate kept in some space thereto, or even if the original has some wrinkle.

If it need not enlarge the illuminating depth, the angle-adjusting material 13 may be unnecessary. Alternatively, the angle-adjusting material 13 may be provided in the bottom of each of the linear illuminating devices 10a and 10b, so that the angle of gradient in each top side of the linear illuminating devices is mutually equal. In this case, the illumination system of relatively large amount of light may be provided for the image sensor 18, because the irradiation range of each of the linear illuminating devices 10a and 10b are identical. In addition, if the irradiation angle of each of the linear illuminating devices 10a and 10b is provided to be different, certain overlapped range may be provided. As a result, the irregular illumination caused by the difference of each illuminating depth may be decreased. Alternatively, if the light-receiving element array includes a plurality of light-receiving lines in the main-scanning direction, the distribution of the amount of light in each light-receiving line may be adjusted to be different. Thus, this results in advantageous effect that the irregular sensitivity of the light-receiving element array may be decreased for the image sensor, or that the speed for reading the image information of the original becomes available without reducing S/N for some application using this image sensor.

Then, a ninth embodiment of an image sensor in accordance with the present invention is described.

### A Ninth Embodiment

FIG. 13 is a cross-sectional view of an image sensor of a ninth embodiment in accordance with the present invention. In this embodiment, the resilient retaining material 6a₁ functions as a part of a case 12c for the light guide 11. The resilient retaining material 6a₁ may be planar-shape along the entire length of the longitudinal direction in the linear illuminating device 10, which is similar to the resilient retaining material 6a₁ shown in FIG. 3. For the resilient retaining material 6a₁ in this embodiment, the part (i.e. top side 11b of the light guide) that functions as a part of the case 12c may be white color. Thereby, the light within the light guide 11 may be efficiently reflected. The light guide 11 may be rectangular-shape, and be arranged so that both surfaces 11b and 11c of the light guide 11 are parallel to each of the resilient retaining material 6a₁, and the bottom of the hollow portion 1a of the frame 1. A reflection material 17 may be provided onto an overhang portion 12c₁ of the case 12c in order to change the direction of the irradiated light from an irradiation surface 11a. The lens array comprises a planar lens array plate 15, and slit 16 for shielding any stray light. According to this embodiment, the image sensor 18 may be extremely miniaturized, because the shape of the light guide 11 may be rectangular-shape, both sides 11b and 11c of the light guide 11 are parallel to the sensor substrate 4, and the lens array is composed of the planar lens array plate 15.

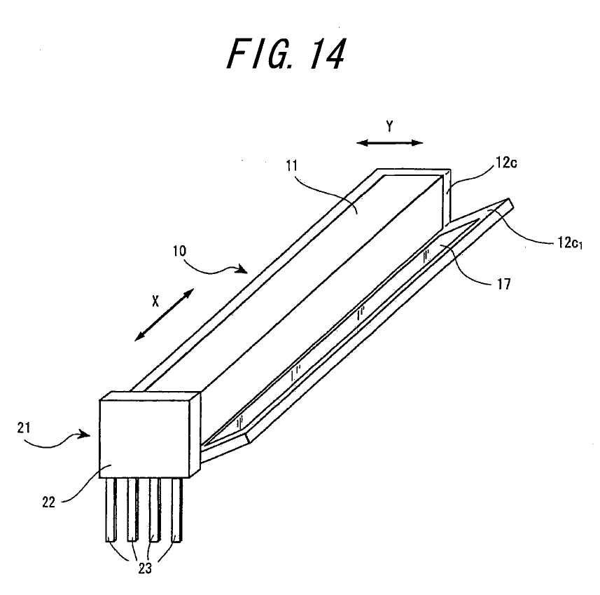

FIG. 14 is a perspective view of a linear illuminating device used for an image sensor of the ninth embodiment in accordance with the present invention. The light guide 11 may be contained in the case 12c. The part to be covered by the resilient retaining material 6a₁ in the light guide 11 (i.e. top side 11b of the light guide shown in FIG. 13) is not covered by the case 12c. An overhang portion 12c₁ may be provided for the case 12c. The reflection material 17 may be provided onto the overhang portion 12c₁. The reflection material 17 may be a mirror, or a reflection sheet or a metallic sheet in the patch form, or may be formed by vapor depositing the metal for a reflection surface. Alternatively, the case 12c may be formed by some material with white color of high-reflectivity without providing the reflection material 17. A light source unit 21 may be arranged in the end of the light guide 11. The light source unit 21 may include three light-emitting elements of R color, G color, and B color on a lead frame (for example, LED). As for the lead frame, the part other than lead terminals 23 for feeding power to the light-emitting elements are contained in a resin housing 22. An aperture to expose the light-emitting elements may be formed in the resin housing 22 (not shown). The irradiated light from the light-emitting elements may be enter within the light guide 11, and be irradiated from irradiation surface of the light guide 11, repeating the reflection/scattering within the light guide. The irradiated light from the light guide 11 may be reflected by the reflection material 17, and irradiated in the predefined direction.

Then, a tenth embodiment of an image sensor in accordance with the present invention is described.

### A Tenth Embodiment

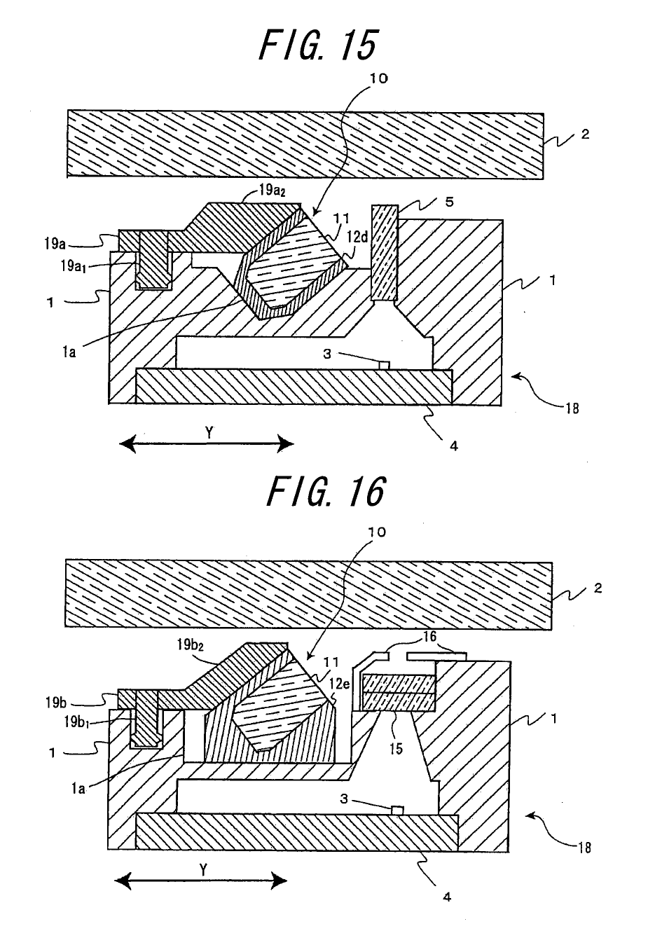

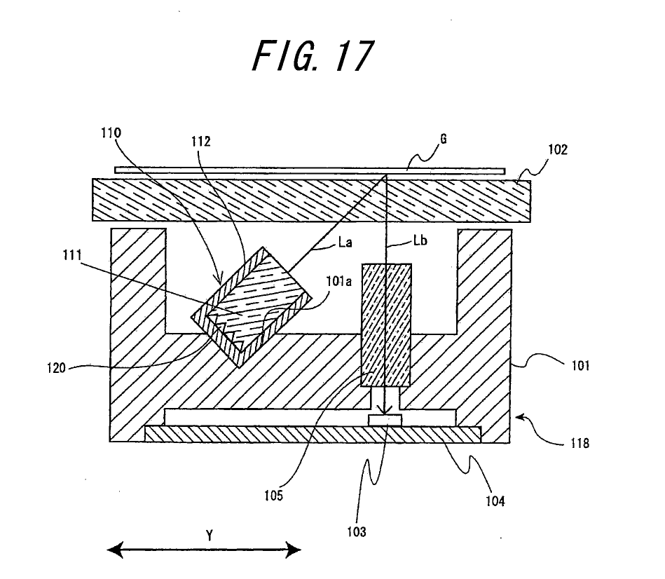

FIG. 15 is a cross-sectional view of an image sensor of a tenth embodiment in accordance with the present invention. The tenth embodiment is a further aspect of the image sensor described by the first embodiment or the second embodiment. In the tenth embodiment, a retaining material 19a may be used instead of the resilient retaining material 6a shown in FIG. 1, and a case 12d that does not include the convex portion 12a₁ may be used instead of providing the convex portion 12a₁ of the side of the case 12a. This image sensor structure is similar to the image sensor structure shown in the first embodiment or the second embodiment, excluding the linear illuminating device 10 fixed by pressing the retaining material 19a into the side of a case 12d. The retaining material 19a may be provided over the entire length of the longitudinal direction in the linear illuminating device 10.

Moreover, the retaining material 19a may be a plurality of retaining materials, such as the resilient retaining materials 6a₂ shown in FIG. 4, and the plurality of retaining materials may be arranged at optional interval along the longitudinal direction of the image sensor 18. If the plurality of retaining materials is used for the retaining material 19a, it is preferable to provide the plurality of retaining materials in the center of the longitudinal direction in the linear illuminating device 10, not only to provide in the two places of both ends thereof in order to suitably suppress the distortion or the warp of the image sensor 18 in the longitudinal direction. That is, it is preferable to provide three or more places of the retaining materials. The retaining material 19a may be combined to the frame 1 with pins (as shown by 19a₁). It is preferable that the retaining material 19a has pin-portions 19a₁ and a retaining portion 19a₂, and that the retaining portion 19a₂ is elastic material. The images sensor 18 may be easily assembled by combining the retaining material 19a to the frame 1 with the pins. Moreover, the retaining material 19a may be made of some prepared retaining portion fixed to the frame 1.

Then, an eleventh embodiment of an image sensor in accordance with the present invention is described.

### An Eleventh Embodiment

FIG. 16 is a cross-sectional view of an image sensor of an eleventh embodiment in accordance with the present invention. The eleventh embodiment is a further aspect of the image sensor described in the fifth embodiment. In the eleventh embodiment, a retaining material 19b may be used instead of the resilient retaining material 6a shown in FIG. 7, and a case 12e that does not include the convex portion 12b, may be used instead of providing the convex portion 12b, of the side of the case 12b. This image sensor structure is similar to the image sensor structure shown in the fifth embodiment, excluding the linear illuminating device 10 fixed by pressing the retaining material 19b into the side of a case 12e. Moreover, the retaining material 19b has pin-portions 19b₁ and a retaining portion 19b₂, and the function and the feature of the retaining material 19b are similar to the function and the feature of the retaining material 19a shown in FIG. 15.

Then, outline of an image reading apparatus including an image sensor in accordance with the present invention is descried. The image reading apparatus may include an image scanner, a facsimile, an electro-photographic apparatus and a multi-device, such as a multi-function printer.

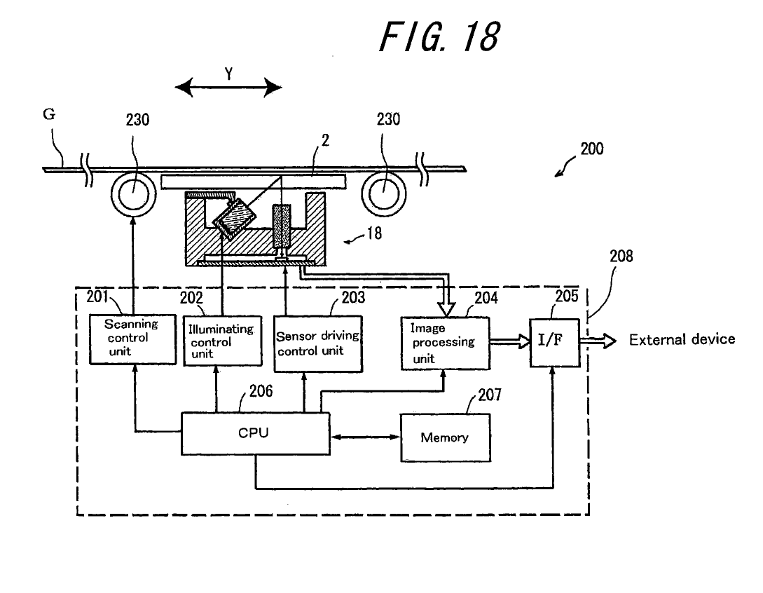

FIG. 18 is a schematic illustration of an image scanner including an image sensor in accordance with the present invention. An image scanner 200 includes an image sensor 18 for reading image information of an original G through light reflected from the original G that is set on an original glass plate 2, a driving device 230 for scanning the original, and a control circuit 208 for controlling the image scanner.

The control circuit 208 includes a scanning control unit 201 for controlling driving of the driving device 230; an illuminating control unit 202 for controlling light-emission of the linear illuminating device provided in the image sensor 18; a sensor driving control unit 203 having a processing portion for receiving of the reflected light from the original G by means of the light-receiving element array provided in the image sensor 18 and for controlling a process of photo-electric conversion; an image processing unit 204 for processing image information corresponding to the photo-electric conversion output obtained by the sensor driving control unit 203; an interface unit 205 for outputting the processed image information to an external device; and memory 207 for storing programs used for the image processing, the interface and the controls; and a center processing unit (CPU) 206 for controlling the scanning control unit 201, the illuminating control unit 202, the sensor driving control unit 203, the image processing unit 204, the interface unit 205 and the memory 207.

In the image reading apparatus shown in FIG. 18, the image sensor 18 is fixed into the image reading apparatus to enable reading the image information of the original by moving the original G. In another aspect of the image reading apparatus, the image sensor 18 may read the image information by scanning the original G, which is fixed, with the image sensor in the sub-scanning direction (i.e. the direction indicated by an arrow Y).

In FIG. 18, although the image reading apparatus using the image sensor of the first embodiment according to the present invention has been described, the image sensor according to any one of the first to eleventh embodiments may be used to similarly operate for the image reading apparatus.

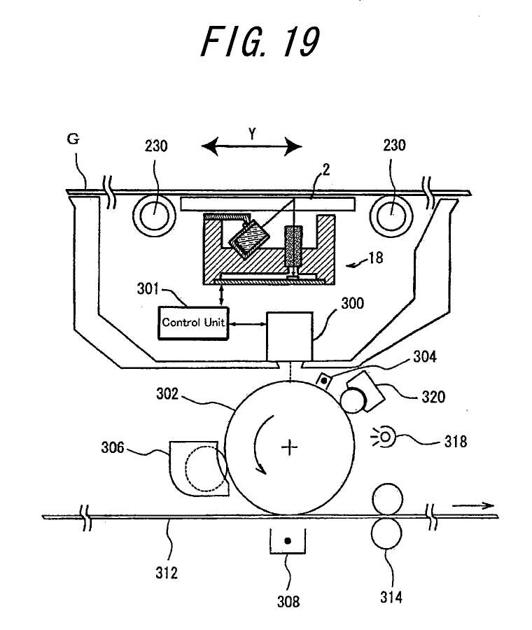

FIG. 19 is a schematic illustration of an electro-photographic apparatus including an image sensor of the first embodiment in accordance with the present invention. In the identical or similar elements shown in FIG. 18, the same reference signs are designated, and the description is omitted.

In the electro-photographic apparatus of FIG. 19, the light emitted by means of a light-emitting element array provided in an optical writing head 300 is irradiated into a cylindrical photosensitive drum 302, by means of a control unit 301 for controlling the image information obtained through the image sensor. A light-conductive material (photosensitive material), such as amorphous Si, is formed on the surface of the cylindrical photosensitive drum 302. This cylindrical photosensitive drum 302 rotates at the printing speed. The whole surface of the cylindrical photosensitive drum 302 is evenly charged by means of a charging device 304 while rotating. Then, the light corresponding to the dot images for printing is irradiated by the optical writing head 300 onto the photosensitive material, and charged portions of the photosensitive material are neutralized by means of the irradiated light. Then, the toner is continuously applied on the photosensitive material with a developing device 306, depending on the state of the charge on the photosensitive material. Then, the toner is transferred on a transported paper 312 by a transfer device 308. The transported paper 312 is heated and fixed with an electro-photographic fixing device 314. Finally, the image information of the original G is copied on the transported paper 312. After the transfer is ended, the charged portions of the photosensitive material are neutralized over the entire surface of the cylindrical photosensitive drum 302 by means of an erasing lamp 318, and the remaining toner on the cylindrical photosensitive drum 302 is removed by means of a cleaning device 320.

In FIG. 19, although the electro-photographic apparatus is described, the electro-photographic apparatus may include other devices, for example, a facsimile and a multi-device, such as a multi-function printer.

Moreover, although the image reading apparatus using the image sensor of the first embodiment according to the present invention has been described in FIG. 18 and FIG. 19, the image sensor according to any one of the first to eleventh embodiments may be applied to the image reading apparatus without limitation by these embodiments.

Moreover, although the linear illuminating device fixed by combining the resilient retaining material and the convex portion of the side of the case has been described in the above embodiments, the resilient retaining material and the linear illuminating device may be combined by providing the linear illuminating device with combining portions, such as prominent portions and/or groove portions.

While the present invention has been described and illustrated with reference to specific exemplary embodiments, it should be understood that many modifications and substitutions could be made without departing from the spirit and scope of the invention. Accordingly, the present invention is not to be considered as limited by the foregoing description but is only limited by the scope of the appended claims.

### INDUSTRIAL APPLICABILITY

According to an image sensor of the present invention, the linear illuminating device may be fixed by the resilient retaining material provided for the frame without using any adhesive or any double-faced tapes, when the linear illuminating device is fixed into the frame of the image sensor. Therefore, the stress is not generated between the linear illuminating device and the frame, even if there is a thermal expansion difference or a thermal contraction difference between the linear illuminating device and the frame. Thus, no trouble, such as warp, to the image sensor occurs. Moreover, since neither the adhesive nor the double-faced tape are used, and the linear illuminating device is fixed to the frame of the image sensor by the resilient retaining material, detaching the linear illuminating device may be facilitated. Therefore, even if a defective characteristic of the image sensor is found due to any failure of the linear illuminating device, the linear illuminating device might be easily exchanged. According to the manufacturing method of the present invention, the alignment of the illuminating device may be easily achieved, and the image sensor with high positional accuracy may be manufactured. Thereby, the present invention is useful for the image reading apparatus using the contact image sensor, for example, an image scanner, a facsimile, an electro-photographic apparatus, or a multi-device, such as a multi-function printer.

1. An image sensor comprising:
a linear illuminating device for illuminating an original;
a light-receiving element array for receiving reflected light from the original;
a lens array for focusing the original on the light-receiving element array;
a frame for containing the linear illuminating device, the lens array, and the light-receiving element array; and
a resilient retaining portion for pressing the linear illuminating device, which is mounted in the frame, into the frame.

2. The image sensor according to claim 1, wherein the resilient retaining portion is a part of the frame.

3. The image sensor according to claim 2, wherein the resilient retaining portion is provided over the entire length of a longitudinal direction in the frame.

4. The image sensor according to claim 2, wherein a plurality of the resilient retaining portions are provided at a plurality of local positions of a longitudinal direction in the frame, respectively.

5. The image sensor according to claim 4, wherein each of the plurality of the resilient retaining portions has a hooking portion to fix the linear illuminating device, and the width of the longitudinal direction of at least one hooking portion differs from the width of the other hooking portions.

6. An image sensor comprising:
a linear illuminating device for illuminating an original;
a light-receiving element array for receiving reflected light from the original;
a lens array for focusing the original on the light-receiving element array;
a frame for containing the linear illuminating device, the lens array, and the light-receiving element array; and
a resilient retaining material for pressing the linear illuminating device, which is mounted in a hollow portion of the frame, into the frame.

7. The image sensor according to claim 6, wherein the linear illuminating device includes a combining portion to be combined with the resilient retaining material.

8. The image sensor according to claim 6, wherein the resilient retaining material is formed at the entire length of a longitudinal direction in the linear illuminating device.

9. The image sensor according to claim 6, wherein a plurality of the resilient retaining materials are formed at a plurality of local positions of a longitudinal direction in the linear illuminating device, respectively.

10. The image sensor according to claim 9, wherein each of the plurality of the resilient retaining materials has a hooking portion to fix the linear illuminating device, and the width of the longitudinal direction of at least one hooking portion differs from the width of the other hooking portions.

11. An image sensor comprising:
a linear illuminating device for illuminating an original;
a light-receiving element array for receiving reflected light from the original; a lens array for focusing the original on the light-receiving element array;
a frame for containing the linear illuminating device, the lens array, and the light-receiving element array; and
a resilient retaining material for pressing the linear illuminating device, which is mounted in a hollow portion of the frame, into the frame;
wherein the width of a shorter-side direction of the hollow portion formed in the frame is longer than the width of the shorter-side direction of the linear illuminating device.

12. The image sensor according to claim 11, wherein the image sensor further comprises an alignment material, which is provided on the hollow portion, for aligning the linear illuminating device in the shorter-side direction.

13. The image sensor according to claim 11, wherein the image sensor further comprises an angle-adjusting material, which is provided on the hollow portion, for adjusting the irradiation angle of the linear illuminating device.

14. The image sensor according to claim 6 or 11, wherein the resilient retaining material and the linear illuminating device are fixed by a combining technique.

15. The image sensor according to claim 1, 6 or 11, wherein the linear illuminating device is composed of two linear illuminating devices provided to be an opposed position in both sides of the lens array.

16. An image sensor comprising:
a linear illuminating device for illuminating an original, the linear illuminating device including a light guide, and a case for covering a part of the light guide;
a light-receiving element array for receiving reflected light from the original;
a lens array for focusing the original on the light-receiving element array;
a frame for containing the linear illuminating device, the lens array, and the light-receiving element array; and
a resilient retaining material for pressing the linear illuminating device, which is mounted in a hollow portion of the frame, into the frame;
wherein the resilient retaining material is formed over longitudinal direction of the linear illuminating device to cover at least one side surface of the light guide, at least one side surface of the light guide being not covered by the case.

17. The image sensor according to claim 16, wherein the image sensor further comprises a reflecting portion provided on a part of the case for reflecting the irradiated light from the light guide.

18. The image sensor according to claim 17, wherein the lens array is composed of at least one or more lens plates that have a plurality of minute lenses in two-dimensional array.

19. An image sensor comprising:
a linear illuminating device for illuminating an original;
a light-receiving element array for receiving reflected light from the original;
a lens array for focusing the original on the light-receiving element array;
a frame for containing the linear illuminating device, the lens array, and the light-receiving element array; and
a detachable retaining material for pressing the linear illuminating device, which is mounted in the frame, into the frame.

20. An image sensor comprising:
a linear illuminating device for illuminating an original;
a light-receiving element array for receiving reflected light from the original;
a lens array for focusing the original on the light-receiving element array;
a frame for containing the linear illuminating device, the lens array, and the light-receiving element array; and
a detachable retaining material for pressing the linear illuminating device, which is mounted in a hollow portion of the frame, into the frame.

21. An image sensor comprising:
a linear illuminating device for illuminating an original;
a light-receiving element array for receiving reflected light from the original;
a lens array for focusing the original on the light-receiving element array;
a frame for containing the linear illuminating device, the lens array, and the light-receiving element array; and
a detachable retaining material for pressing the linear illuminating device, which is mounted in a hollow portion of the frame, into the frame;
wherein the width of a shorter-side direction of the hollow portion formed in the frame is longer than the width of the shorter-side direction of the bottom of the linear illuminating device.

22. An image reading apparatus including the contact image sensor as claimed in any one of claims 1, 6, 11, 19, 20 and 21.

23. A method for manufacturing an image sensor, in which the image sensor comprises a linear illuminating device for illuminating an original; a light-receiving element array for receiving reflected light from the original; a lens array for focusing the original on the light-receiving element array; a frame for containing the linear illuminating device, the lens array, and the light-receiving element array; and a resilient retaining material for pressing the linear illuminating device, which is mounted in the frame, into the frame; the method comprising the steps of:
arranging an alignment material for aligning the linear illuminating device into the hollow portion;
arranging the linear illuminating device within the hollow portion based on the arrangement of the alignment material;
fixing the resilient retaining material to the frame and to the linear illuminating device; and
removing the alignment material after fixing the linear illuminating device into the frame using the alignment material.
